(19) United States
(12) Patent Application Publication
(10) Pub. No.: US 2025/0068080 A1
(43) Pub. Date: Feb. 27, 2025

(54) SUBSTRATE TREATMENT APPARATUS AND SUBSTRATE TREATMENT METHOD

(71) Applicant: SEMES CO., LTD., Cheonan-si (KR)

(72) Inventors: Kyung Taek IM, Cheonan-si (KR); Jae Ha KIM, Suwon-si (KR); Seung Hwan LEE, Cheonan-si (KR); Seung Jun LEE, Seoul (KR)

(21) Appl. No.: 18/743,089

(22) Filed: Jun. 13, 2024

(30) Foreign Application Priority Data
Aug. 22, 2023 (KR) 10-2023-0109757

(51) Int. Cl. G03F 7/38; H01L 21/67

(52) U.S. Cl. CPC G03F 7/38; H01L 21/67103; H01L 21/67109

(57) ABSTRACT

Provided is a substrate treatment apparatus including: a cooling chamber accommodating a substrate; and a cooling unit disposed inside the cooling chamber, the cooling unit including a support, two first plates connected to the support to support the substrate and spaced apart from each other in a height direction of the support, and a second plate disposed to move up and down between the two first plates.

### CROSS-REFERENCE TO RELATED APPLICATION(S)

This application claims benefit of priority to Korean Patent Application No. 10-2023-0109757 filed on Aug. 22, 2023 in the Korean Intellectual Property Office, the disclosure of which is incorporated herein by reference in its entirety.

### BACKGROUND

### 1. Field

The present disclosure relates to a substrate treatment apparatus and a substrate treatment method.

### 2. Description of Related Art

Among semiconductor manufacturing processes, a photolithography process is a process of forming a desired pattern on a wafer. The photolithography process mainly includes a photosensitive liquid applying process, an exposure process, and a development process. In addition, a substrate baking process of performing heat treatment on a substrate is performed before or after the exposure process.

In the baking process, a substrate is mounted on a heating plate, the substrate is heat-treated by operating a heater provided inside the heating plate, and then the substrate is cooled.

According to the conventional art, in order to cool the heated substrate, the substrate is mounted on a cooling plate. Since the substrate is mounted on the cooling plate in a state in which only a lower surface of the substrate is in contact with the cooling plate, there is a problem in that the substrate may not be quickly cooled, for example, because an upper surface of the substrate is affected by external heat.

### SUMMARY

An aspect of the present disclosure may provide a substrate treatment apparatus and a substrate treatment method capable of rapidly cooling a substrate to enhance cooling performance, thereby improving the substrate treatment amount and the substrate treatment rate of the substrate treatment apparatus.

According to an aspect of the present disclosure, a substrate treatment apparatus may include: a cooling chamber accommodating a substrate; and a cooling unit disposed inside the cooling chamber, the cooling unit including a support, two first plates connected to the support to support the substrate and spaced apart from each other in a height direction of the support, and a second plate disposed to move up and down between the two first plates.

According to another aspect of the present disclosure, a substrate treatment method may include: seating a substrate on a first plate cooling the substrate; moving a second plate down toward the substrate; cooling the substrate using the second plate, together with the first plate; and moving the second plate up after completely cooling the substrate.

According to another aspect of the present disclosure, a substrate treatment apparatus may include: a baking chamber heating a substrate for heat treatment; a cooling chamber disposed on one side of the baking chamber, and accommodating the substrate heat-treated in the baking chamber; and a cooling unit disposed inside the cooling chamber, the cooling unit including a support, two first plates connected to the support to support the substrate and spaced apart from each other in a height direction of the support, and a second plate, movable up and down between the two first plates, and disposed in parallel with the two first plates, wherein the second plate has a projection projecting downwardly from a lower surface thereof by a projection distance longer than a thickness of the substrate and extending a in circumferential direction of the second plate.

The cooling unit and the substrate treatment apparatus including the same, according to the exemplary embodiments of the present disclosure, are capable of simultaneously cooling upper and lower surfaces of the substrate using the second plate pre-cooled by the first plate and the first plate, thereby increasing the cooling rate as compared with that in a case in which the substrate is cooled using only the first plate, and as a result, improving the substrate treatment amount and substrate treatment performance of the substrate treatment apparatus.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a diagram of a substrate treatment apparatus according to an exemplary embodiment 41 of the present disclosure when viewed from above;

FIG. 2 is a diagram of the substrate treatment apparatus of FIG. 1 when viewed in a A-A direction;

FIG. 3 is a diagram of the substrate treatment apparatus of FIG. 1 when viewed in a B-B direction;

FIG. 4 is a side view illustrating a cooling unit according to an exemplary embodiment of the present disclosure;

FIG. 5 is a side view illustrating a partial portion of the cooling unit of FIG. 4;

FIG. 6 is a side view illustrating a state in which a second plate moves down toward a substrate supported on a first plate of the cooling unit of FIG. 4;

FIG. 7 is a side view illustrating a state in which the second plate has moved to a cooling position adjacent to the substrate of the cooling unit of FIG. 4;

FIG. 8 illustrates a substrate cooled by a second plate and a first plate according to an exemplary embodiment of the present disclosure;

FIG. 9 illustrates a substrate cooled by a second plate and a first plate according to an exemplary embodiment of the present disclosure;

FIG. 10A illustrates a projection according to an exemplary embodiment of the present disclosure, and FIG. 10B illustrates a projection according to an exemplary embodiment of the present disclosure;

FIG. 11 illustrates a substrate cooled by a second plate and a first plate according to an exemplary embodiment of the present disclosure;

FIG. 12 illustrates a substrate cooled by a second plate and a first plate according to an exemplary embodiment of the present disclosure;

FIG. 13 illustrates a substrate cooled by a second plate and a first plate according to an exemplary embodiment of the present disclosure;

FIG. 14 illustrates a substrate cooled by a second plate and a first plate according to an exemplary embodiment of the present disclosure; and

FIG. 15 is a flowchart illustrating a process in which a cooling unit cools a substrate according to an exemplary embodiment of the present disclosure.

### DETAILED DESCRIPTION

Hereinafter, preferred exemplary embodiments will be described in detail with reference to the attached drawings so that those having ordinary knowledge in the art to which the present disclosure pertains could easily carry out the present disclosure. However, in describing the preferred exemplary embodiments of the present disclosure in detail, detailed descriptions of relevant known functions or configurations will be omitted if deemed unnecessarily obscuring the gist of the present disclosure. In addition, parts performing similar functions and actions will be denoted by the same reference numerals throughout the drawings. In addition, in the present specification, terms ‘on’, ‘upper’, ‘top’, ‘under’, ‘lower’, ‘bottom, and the like are based on the drawings, and terms ‘inside’, ‘outside’, and the like are based on the outer perimeters of corresponding components, and may vary depending on directions in which elements or components are actually disposed.

In addition, throughout the specification, “including” a certain component means that another component may be further included rather than excluding another component unless specifically stated to the contrary.

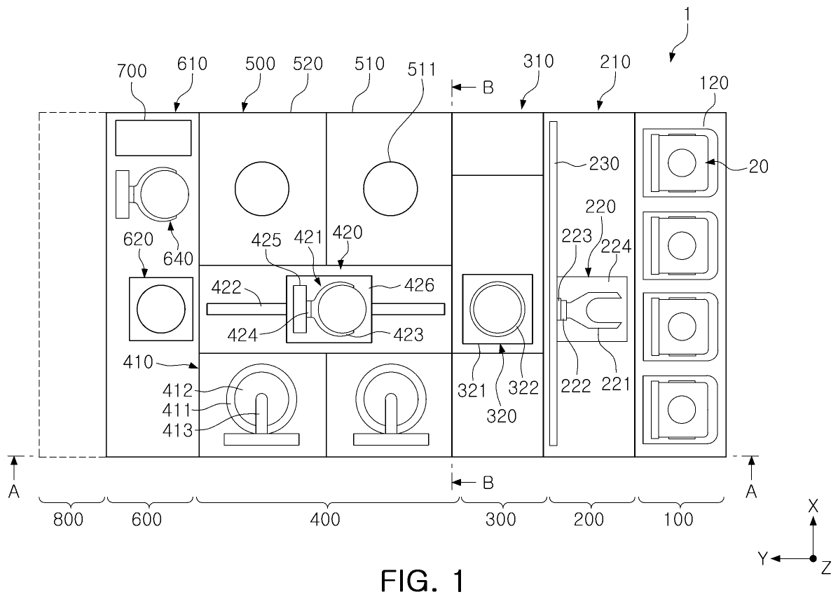

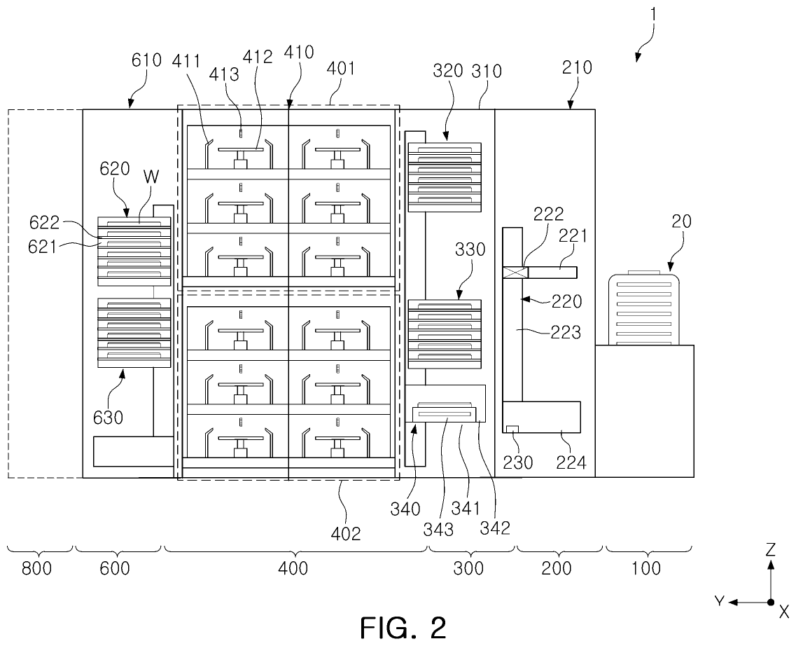

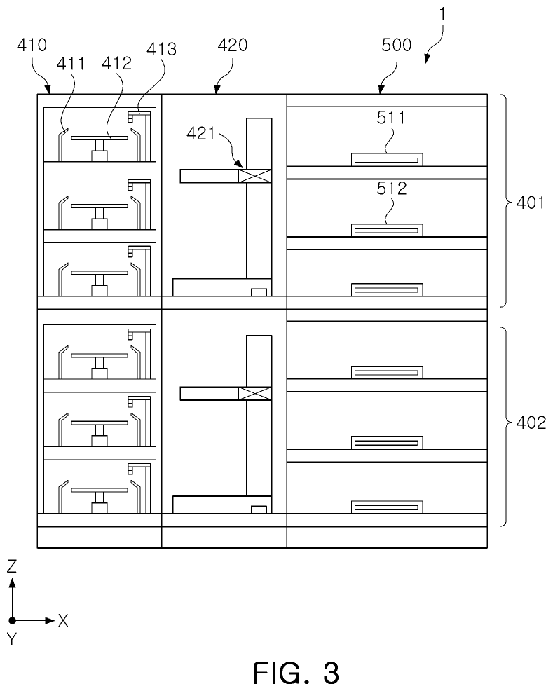

FIG. 1 is a diagram of a substrate treatment apparatus when viewed from above, FIG. 2 is a diagram of the substrate treatment apparatus of FIG. 1 when viewed in a A-A direction, and FIG. 3 is a diagram of the substrate treatment apparatus of FIG. 1 when viewed in a B-B direction.

Referring to FIGS. 1 to 3, the substrate treatment apparatus 1 may include a load port 100, an index module 200, a buffer module 300, an application and development module 400, and a purge module 700. The load port 100, the index module 200, the buffer module 300, the application and development module 400, and an interface module 600 may be sequentially arranged in a line in one direction. The purge module 700 may be provided within the interface module 600. Alternatively, the purge module 700 may be provided at any of various locations, such as in a location in which an exposure device is connected behind the interface module 600 or on a lateral side of the interface module 600.

Hereinafter, a direction in which the load port 100, the index module 200, the buffer module 300, the application and development module 400, and the interface module 600 are arranged will be referred to as a first direction Y, a direction perpendicular to the first direction Y when viewed from above will be referred to as a second direction X, and a direction perpendicular to each of the first direction Y and the second direction X will be referred to as a third direction Z.

A substrate W may be moved in a state in which it is stored in a cassette 20. The cassette 20 may have a structure to be sealed from the outside. As an example, a front open unified pod (FOUP) having a door at the front may be used as the cassette 20.

Hereinafter, the load port 100, the index module 200, the buffer module 300, the application and development module 400, the interface module 600, and the purge module 700 will be described in detail.

The load port 100 may have a mounting table 120 on which the cassette 20 accommodating the substrate W is disposed. A plurality of mounting tables 120 may be provided, the mounting tables 120 being arranged in a row in the second direction X. Although it is illustrated as an example in FIG. 1 that four mounting tables are provided, the number of mounting tables may be changed.

The index module 200 may transfer the substrate W between the cassette 20 disposed on the mounting table 120 of the load port 100 and the buffer module 300. The index module 200 may include a frame 210, an index robot 220, and a guide rail 230.

The frame 210 may be provided in a rectangular parallelepiped shape with the inside thereof being generally empty, and disposed between the load port 100 and the buffer module 300. The frame 210 of the index module 200 may be provided at a height lower than that of a frame 310 of the buffer module 300.

The index robot 220 and the guide rail 230 may be disposed within the frame 210. The index robot 220 may be provided in such a manner that a manipulator 221 that directly handles the substrate W is movable and rotatable in the first direction Y, the second direction X, and the third direction Z. The index robot 220 may include a manipulator 221, an arm 222, a support 223, and a holder 224. The manipulator 221 may be installed to be fixed to the arm 222. The arm 222 may be provided in a stretchable structure or a rotatable structure. The support 223 may be disposed in such a manner that a length direction thereof is oriented in the third direction Z. The arm 222 may be coupled to the support 223 in such a manner as to be movable along the support 223. The support 223 may be fixedly coupled to the holder 224. The guide rail 230 may be disposed in such a manner that a length direction thereof is oriented in the second direction X. The holder 224 may be coupled to the guide rail 230 in such a manner as to be linearly movable along the guide rail 230. In addition, although not illustrated, the frame 210 may further include a door opener opening and closing the door of the cassette 20.

The buffer module 300 may include a frame 310, a first buffer 320, a second buffer 330, and a cooling chamber 340. The frame 310 may be provided in a rectangular parallelepiped shape with the inside thereof being generally empty, and disposed between the index module 200 and the application and development module 400. The first buffer 320, the second buffer 330, and the cooling chamber 340 may be located within the frame 310. The cooling chamber 340, the second buffer 330, and the first buffer 320 may be sequentially arranged in the third direction Z from below. The first buffer 320 may be located at a height corresponding to an application module 401 of the application and development module 400, and the second buffer 330 and the cooling chamber 340 may be provided at a height corresponding to a development module 402 of the application and development module 400.

Each of the first buffer 320 and the second buffer 330 may temporarily store the plurality of substrate W. The first buffer 320 may include a housing 321 and a plurality of supports 322. In the first buffer 320, the supports 322 may be disposed within the housing 321 and spaced apart from each other along the third direction Z. The second buffer 330 may include a housing 331 and a plurality of supports 332. In the second buffer 330, the supports 332 may be disposed within the housing 331 and spaced apart from each other along the third direction Z. One substrate W may be disposed on each support 322 of the first buffer 320 and each support 332 of the second buffer 330. The housing 331 may have an opening in a direction in which the index robot 220 is provided so that the index robot 220 may load or unload the substrate W onto or from the support 332 within the housing 331.

The first buffer 320 has a generally similar structure to the second buffer 330. However, the housing 321 of the first buffer 320 may have openings in a direction in which a first buffer robot 360 is provided and in a direction in which an applicator robot 421 located in the application module 401 is provided. The number of supports 322 provided in the first buffer 320 and the number of supports 332 provided in the second buffer 330 may be the same or different. According to one example, the number of supports 332 provided in the second buffer 330 may be greater than the number of supports 322 provided in the first buffer 320.

The cooling chamber 340 may cool each substrate W. The cooling chamber 340 may include a housing 341 and a cooling plate 342. The cooling plate 342 may include a cooling means 343 for cooling an upper surface on which the substrate W is disposed and the substrate W. As the cooling means 343, any of various cooling methods may be used, such as a coolant or a thermoelectric element. In addition, the cooling chamber 340 may be provided with a lift pin assembly that positions the substrate W on the cooling plate 342. The housing 341 may have openings in a direction in which the index robot 220 is provided and in a direction in which a developer robot provided in the development module 402 is provided, so that the index robot 220 and the developer robot may load or unload the substrate W onto or from the cooling plate 342. In addition, the cooling chamber 340 may be provided with doors that open and close the above-described openings.

Although the configuration of the cooling chamber 340 is included in the buffer module 300 in the above-described exemplary embodiment, the present disclosure is not limited thereto, and the configuration of the cooling chamber 340 may be omitted if necessary.

The application module 401 may perform a process of applying a photosensitive liquid such as a photoresist onto the substrate W, and a heat treatment process such as heating and cooling the substrate W before and after the resist application process. The application module 401 may include an application chamber 410, a heat treatment chamber part 500, and a transfer chamber 420. The application chamber 410, the transfer chamber 420, and the heat treatment chamber part 500 may be sequentially arranged in the second direction X. That is, based on the transfer chamber 420, the application chamber 410 may be provided on one side of the transfer chamber 420, and the heat treatment chamber part 500 may be provided on the other side of the transfer chamber 420.

A plurality of application chambers 41 may be provided in the third direction Z. In addition, a plurality of application chambers 410 may be provided in the first direction Y as illustrated in FIG. 1, or one application chamber 410 may be provided in the first direction Y.

The heat treatment chamber part 500 may include a baking chamber 510 and a cooling chamber 520, and a plurality of baking chambers 510 and a plurality of cooling chambers 520 may be provided in the third direction Z. The transfer chamber 420 may be positioned to be aligned with the first buffer 320 of the buffer module 300 in the first direction Y. An applicator robot 421 and a guide rail 422 may be located within the transfer chamber 420. The transfer chamber 420 may have a generally rectangular shape. The applicator robot 421 may transfer the substrate W between the baking chamber 510, the cooling chamber 520, the application chamber 410, and the first buffer 320 of the buffer module 300.

The guide rail 422 may be disposed in such a manner that a length direction thereof is parallel to the first direction Y. The guide rail 422 may guide the applicator robot 421 to move linearly in the first direction Y. The applicator robot 421 may include a manipulator 423, an arm 424, a support 425, and a holder 426. The manipulator 423 may be installed to be fixed to the arm 424. The arm 424 may be provided in a stretchable structure so that the manipulator 423 is movable in the horizontal direction. The support 425 may be disposed in such a manner that a length direction thereof is oriented in the third direction Z. The arm 424 may be coupled to the support 425 in such a manner as to be linearly movable in the third direction Z along the support 425. The support 425 is fixedly coupled to the holder 426, and the holder 426 may be coupled to the guide rail 422 so as to be movable along the guide rail 422.

All of the application chambers 410 may have the same structure, but types of treatment solutions used in the respective application chambers 410 may be different. As a treatment solution, a treatment solution for forming a photoresist film or an anti-reflection film may be used.

The application chamber 410 may apply the treatment solution on the substrate W. The application chamber 410 may be provided with a treatment unit including a treatment vessel 411, a support part 412, and a nozzle part 413.

One treatment unit is arranged along the first direction Y in each application chamber 410 as an example, but the present invention is not limited thereto, and two or more treatment units may be disposed in one application chamber 410. All of the treatment units may have the same structure. However, types of treatment solutions used in the respective treatment units may be different.

The treatment vessel 411 of the application chamber 410 may have an upside-open shape. The support part 412 may be located within the treatment vessel 411 and support the substrate W. The support part 412 may be provided rotatably. The nozzle part 413 may supply the treatment solution onto the substrate W disposed on the support part 412. The treatment solution may be applied onto the substrate W in a spin coat scheme. In addition, the application chamber 410 may optionally be further provided with a nozzle (not illustrated) that supplies a cleaning solution such as deionized water (DIW) to clean the surface of the substrate W on which the treatment solution is applied and a back-rinse nozzle (not illustrated) for cleaning the lower side of the substrate W.

In the baking chamber 510, when the substrate W is seated by the applicator robot 421, the substrate W is heat-treated.

In the baking chamber 510, a prebake process may be performed to heat the substrate W to a predetermined temperature before applying the treatment solution to remove organic matter or moisture from the surface of the substrate W, or a soft bake process or the like may be performed after applying the treatment solution onto the wafer W. After each heating process, a cooling process for cooling the substrate W may be performed.

The baking chamber 510 includes a heating plate 511 and a first plate 512, which will be described below.

In the cooling chamber 520, a cooling process is performed to cool the substrate W before applying the treatment solution. A cooling unit CU may be disposed in the cooling chamber 520. The cooling unit CU includes a first plate 512 cooling the substrate W, and details with regard thereto will be described later.

The interface module 600 may connect the application and development module 400 to an external exposure device 800. The interface module 600 may include an interface frame 610, a first interface buffer 620, a second interface buffer 630, and a transfer robot 640. The transfer robot 640 may transfer, to the exposure device 800, the substrate transferred to the first and second interface buffers 620 and 630 after the operation of the application and development module 400 is completed. The first interface buffer 620 may include a housing 621 and a support 622, and the transfer robot 640 and the applicator robot 421 may load or unload the substrate W onto or from the support 622.

The substrate treatment apparatus having such configurations may perform a photo treatment process by spraying various types of treatment solutions onto the substrate. Here, since, the substrate is discharged out of the chamber in a high-temperature state before the treatment solution is applied onto the substrate or after the substrate has been treated by applying the treatment solution or the like, the substrate is cooled to proceed with the subsequent process. The above-described cooling unit CU is used to cool such a substrate, and configurations of the cooling unit CU and the substrate treatment apparatus 1 according to various exemplary embodiments of the present disclosure will be described with reference to the drawings.

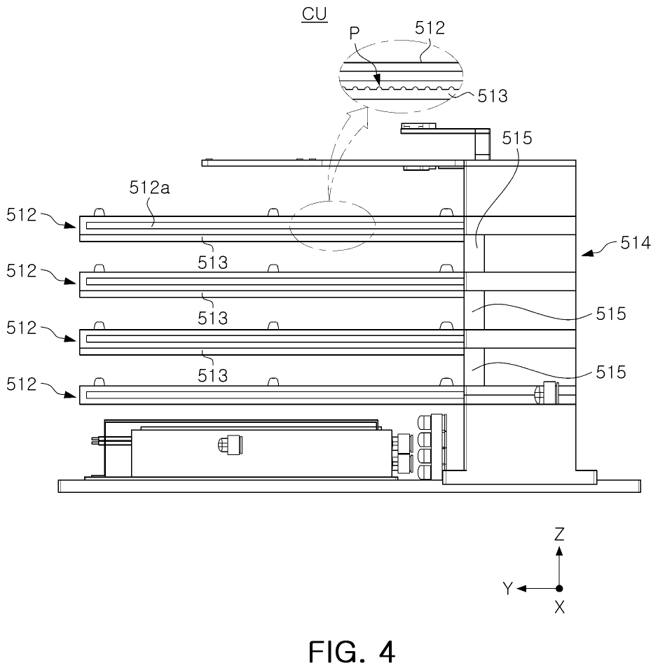

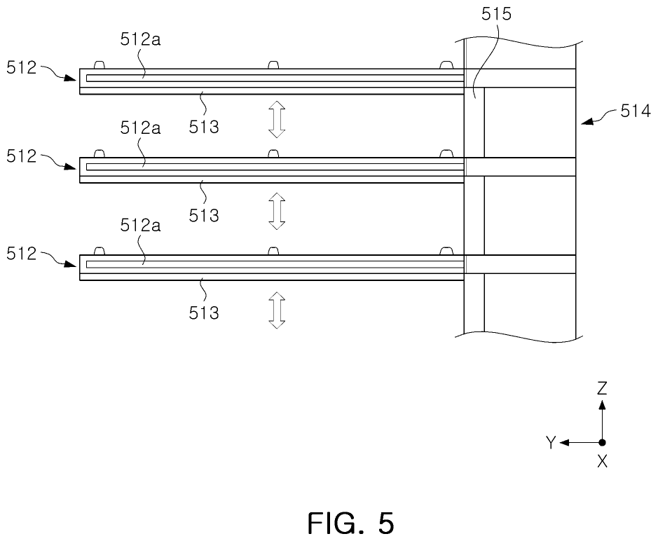

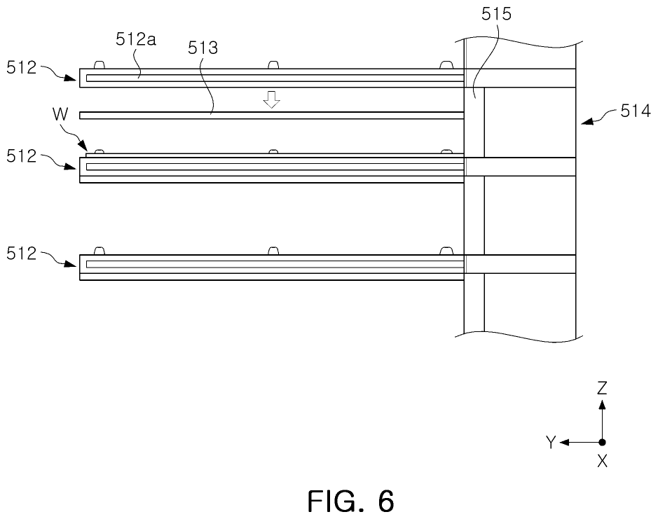

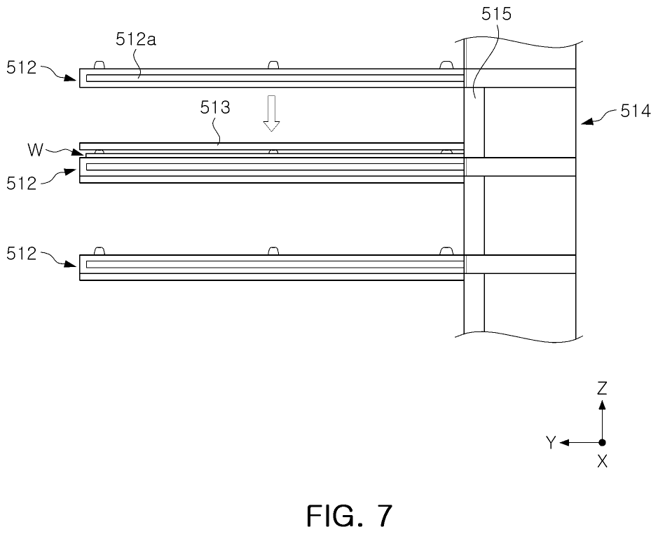

FIG. 4 is a side view illustrating a cooling unit according to an exemplary embodiment of the present disclosure, and FIG. 5 is a side view illustrating a partial portion of the cooling unit of FIG. 4. FIG. 6 is a side view illustrating a state in which a second plate moves down toward a substrate supported on a first plate of the cooling unit of FIG. 4, and FIG. 7 is a side view illustrating a state in which the second plate has moved to a cooling position adjacent to the substrate of the cooling unit of FIG. 4.

Referring to FIGS. 4 to 7, the cooling unit CU, which cools the substrate W heated in the bake process, may include a first plate 512, a second plate 513, a support 514, and a driving part 515. The first plate 512 may be disposed on the support 514. More specifically, the first plate 512 may be disposed in such a manner that one end thereof is connected to the support 514 and the other end thereof extends in the second direction Y and protrudes outwardly of the support 514.

The first plate 512 may include a cooling means 512a for cooling the substrate W. As an example, the cooling means 512a may be formed by providing a cooling passage (not illustrated) inside the first plate 512, and connecting a coolant inlet (not illustrated) and a coolant outlet (not illustrated) to the cooling passage. In this case, a coolant supplied through the coolant inlet may exchange heat with the substrate W while passing through the cooling passage, and then be discharged through the coolant outlet, thereby cooling the substrate W. However, the present disclosure is not limited thereto, and any of various cooling methods such as a thermoelectric element or a phase change material may be used as the cooling means 512a.

The second plate 513 may be disposed below the first plate 512. The second plate 513 may be disposed to be movable back and forth along one direction below the first plate 512. Here, one direction refers to a height direction of the support 514, that is, the third direction Z, and accordingly, the second plate 513 may move up and down in the vertical direction below the first plate 512.

The driving part 515 may provide a driving force for the second plate 513 to move up and down. The driving part 515 may be disposed inside the support 514 or on one side of the support 514, and the second plate 513 may be connected to the driving part 515. More specifically, one end of the second plate 513 may be connected to the driving part 515, and the other end of the second plate 513 may extend in the second direction Y and protrude outward of the support 514. Accordingly, the second plate 513 may face the first plate 512 in a parallel state. The driving part 515 may be constituted by, for example, an actuator using pneumatic pressure or hydraulic pressure, or a linear motor operated by electromagnetic interaction. By the driving part 515, the second plate 513 may be moved up and down.

A plurality of first plates 512 may be provided. The plurality of first plates 512 may be connected to the support 514 in such a manner as to be spaced apart from each other at predetermined intervals in a length direction of the support 514, that is, the third direction Z. In this case, a plurality of second plates 513 may also be provided, each one being disposed below each of the first plates 512. Accordingly, the second plate 513 may move up and down between two adjacent first plates 512 among the plurality of first plates 512.

Meanwhile, no second plate 513 may be disposed below the lowermost first plate 512 among the plurality of first plates 512. In addition, the substrate W may be temporarily stored on the uppermost first plate 512 before cooling is initiated or after cooling is completed.

In addition, a plurality of driving parts 515 may also be provided to correspond to the second plates 513. Each of the driving parts 515 may be connected to one second plate 513 to provide a driving force thereto. Accordingly, the second plates 513 may be driven individually to move up and down simultaneously or at different times.

Before cooling the substrate W or moving the second plate 513 down, the second plate 513 may be disposed under the upper one of two adjacent first plates 512 among the first plates 512. At this time, the second plate 513 may be disposed in a state in which its upper surface is in contact with a lower surface of the first plate 512. At this time, the second plate 513 may have a plurality of protrusions P protruding upward on an upper surface thereof, as illustrated in the enlarged view of FIG. 4. In addition, the first plate 512 may have a plurality of grooves corresponding to the above-described protrusions P on a lower surface thereof. These protrusions P and grooves make it possible to increase a contact area between the first and second plates 512 and 513. As a result, it is possible to improve a rate and a performance with which the first plate 512 cools the second plate 513.

When the substrate W is transported to the first plate 512, the second plate 513 may move down toward the lower one of two adjacent first plates 512. The second plate 513 may move to a position (hereinafter referred to as a cooling position) adjacent to the substrate W supported on the first plate 512 disposed below the second plate 513 as described above. Here, the cooling position may refer to a position where the lower surface of the second plate 513 is separated from the upper surface of the substrate W by a predetermined distance, but is close enough to exchange heat with each other.

At this cooling position, since the second plate 513 is separated from the substrate W at the predetermined distance, the lower surface of the second plate 513 and the upper surface of the substrate W may not contact each other. More specifically, when the second plate 513 is located at the cooling position, the lower surface of the second plate 513 may be spaced apart from the upper surface of the substrate W by a preset separation distance D2. The preset separation distance D2 is an optimal distance at which heat can be exchanged between the substrate W and the second plate 513, and may be shorter than a thickness D1 of the substrate W. The above-described separation distance D2 may be set, for example, by adjusting a rotation speed of the motor used in the driving part 515.

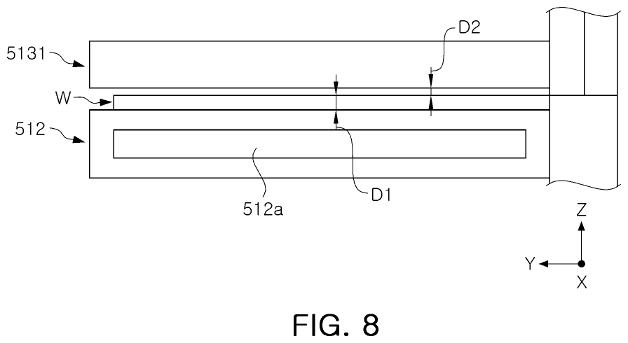

FIG. 8 illustrates a substrate cooled by a second plate and a first plate according to an exemplary embodiment of the present disclosure.

Referring to FIG. 8, a second plate 5131 according to an exemplary embodiment (hereinafter, a first exemplary embodiment) of the present disclosure may be in the form of a thin plate. The second plate 5131 may have a cross-sectional shape corresponding to the first plate 512. For example, when viewed from above the cooling unit CU, in a case in which the first plate 512 has a circular cross section, the second plate 5131 may also have a circular cross section. In addition, the second plate 5131 and the first plate 512 may have the same area or similar areas. At this time, the second plate 5131 and the first plate 512 may have a larger area than the substrate W so as to entirely cover the substrate W. Accordingly, when viewed from the side of the substrate W, the second plate 5131 and the first plate 512 may have a longer length than the substrate W.

The second plate 5131 may be manufactured from a material having a high heat transfer rate. The material of the second plate 5131 may be, for example, aluminum, but is not limited thereto. The second plate 5131, made of a material having a high heat transfer rate, may cool the substrate W by exchanging heat with the heated substrate W at a location adjacent to the upper surface of the substrate W.

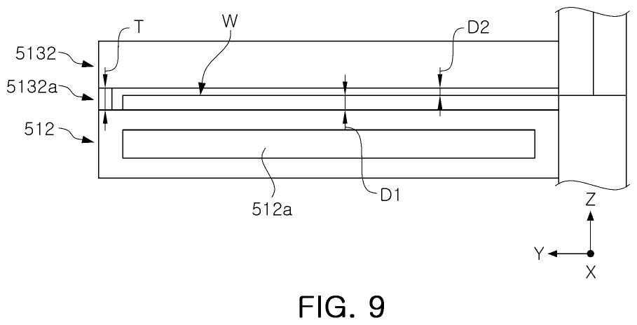

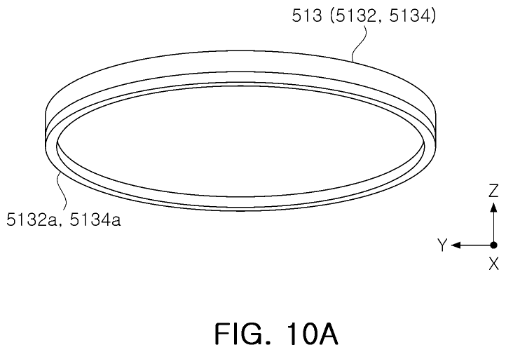

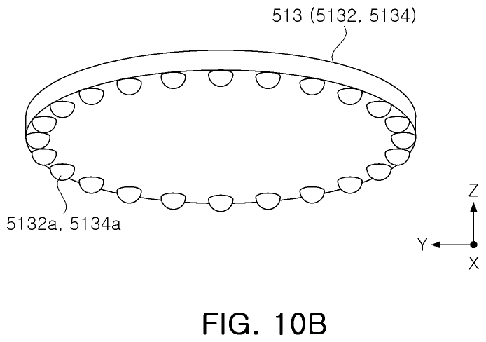

FIG. 9 illustrates a substrate cooled by a second plate and a first plate according to an exemplary embodiment of the present disclosure, FIG. 10A illustrates a projection according to an exemplary embodiment of the present disclosure, and FIG. 10B illustrates a projection according to an exemplary embodiment of the present disclosure.

Referring to FIGS. 9 and 10, a second plate 5132 according to an exemplary embodiment (hereinafter, a second exemplary embodiment) of the present disclosure may be in the form of a disk having a circular cross section when viewed from above, similarly to the second plate according to the first exemplary embodiment described above. At this time, the second plate 5132 may have a projection 5132a.

The projection 5132a may be formed to project downward from the lower surface of the second plate 5132. Based on the third direction Z, the projection distance T of the projection 5132a may be formed to be longer than the thickness of the substrate W. In addition, the projection 5132a may be disposed at an outer end portion, that is, an edge portion, of the second plate 5132. At this time, as illustrated in FIG. 10A, the projection 5132a may be formed in a ring or ring-like shape by extending along a perimeter direction (e.g., a circumferential direction) of the second plate 5132. As another example, as illustrated in FIG. 10B, a plurality of projections 5132a may be provided, and arranged to be spaced apart from each other along the circumferential direction of the second plate 5132.

The projection 5132a makes it possible to prevent the second plate 5132 and the projection 5132a from being in direct contact with the substrate W, because the projection 5132a comes into contact with the upper surface of the lower first plate 512 when the second plate 5132 moves down to the cooling position.

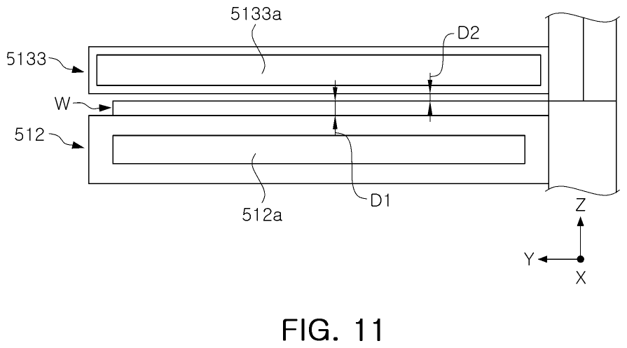

FIG. 11 illustrates a substrate cooled by a second plate and a first plate according to an exemplary embodiment of the present disclosure.

Referring to FIG. 11, a second plate 5133 according to an exemplary embodiment (hereinafter, a third exemplary embodiment) of the present disclosure may include a cooling auxiliary means 5133a.

The cooling auxiliary means 5133a may be disposed inside the second plate 5133. In this case, the second plate 5133 may be in the form of a chamber having an internal space inside. As an example, the second plate 5133 may be in the form of a disk having a circular cross section when viewed from above, but is not limited thereto.

The cooling auxiliary means 5133a may be a working fluid accommodated inside the internal space of the second plate 5133. The working fluid may be evaporated by an external heat source, and the evaporated vapor may be condensed by moving to another side where no heat is applied, thereby transferring heat inside the chamber. As an example, vapor may be used as a working fluid. The cooling auxiliary means 5133a, which is a working fluid, is vaporized by heat absorbed from the heated substrate W, and then cooled and reliquefied. As a result, the cooling auxiliary means 5133a can improve the substrate cooling performance of the cooling unit CU by absorbing heat from the substrate W and discharging the absorbed heat to the outside of the second plate 5133.

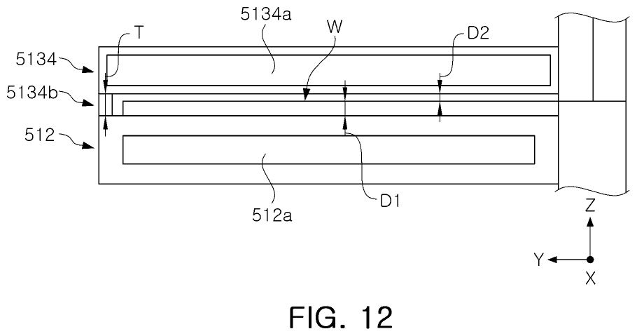

FIG. 12 illustrates a substrate cooled by a second plate and a first plate according to an exemplary embodiment of the present disclosure.

Referring to FIGS. 10 and 12, a second plate 5134 according to an exemplary embodiment (hereinafter, a fourth exemplary embodiment) of the present disclosure may include a cooling auxiliary means 5134a. At this time, since the specific features of the cooling auxiliary means 5134a are the same as or similar to the cooling auxiliary means according to the third exemplary embodiment described above, overlapping descriptions will be omitted.

The second plate 5134 may further include a projection 5134b. The projection 5134b may project downward from the lower surface of the second plate 5134, and may be disposed at an outer end portion of the second plate 5134. The other specific features of the projection 5134b are the as or similar to those in the second exemplary embodiment described above, and the projection 5134b makes it possible to prevent the second plate 5134 from being directly in contact with the substrate W at the cooling position.

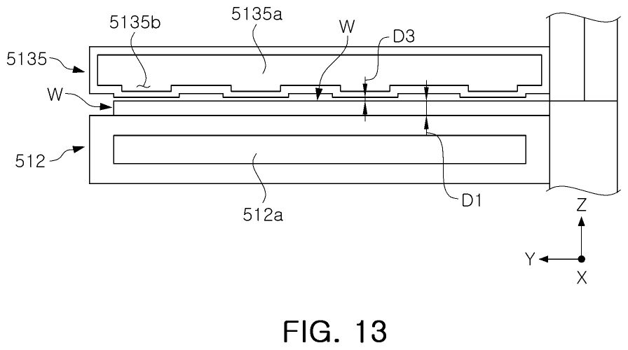

FIG. 13 illustrates a substrate cooled by a second plate and a first plate according to an exemplary embodiment of the present disclosure.

Referring to FIG. 13, a second plate 5135 according to an exemplary embodiment (hereinafter, a fifth exemplary embodiment) of the present disclosure may include a cooling auxiliary means 5135a. The cooling auxiliary means 5135a may be disposed inside the second plate 5135. At this time, the second plate 5135 may be a disc-shaped chamber having an internal space inside.

The internal space of the second plate 5135 may have an internal groove 5135b. The internal groove 5135b may be formed to be recessed downward from the bottom surface of the internal space. In this case, a partial portion of the lower surface of the second plate 5135 corresponding to the internal groove 5135b may project downward. At this time, the projecting portion of the second plate 5135 and the substrate W may be separated from each other by a separation distance D3 shorter than the thickness D1 of the substrate W. However, the present disclosure is not limited thereto, and the lower surface of the second plate 5135 may be formed in a flat shape although the internal groove 5135b is formed in the internal space.

A plurality of internal grooves 5135b may be provided. A plurality of projections 5134b may be arranged to be spaced apart from each other on the bottom surface of the internal space along the length direction Y. In this case, the projections 5134b are arranged at equal or similar intervals, but are not limited thereto.

The cooling auxiliary means 5135a is a working fluid, similarly to those in the exemplary embodiments described above. As described above, the substrate W may be cooled by absorbing heat from the substrate W and discharging the absorbed heat to the outside through vaporization and liquefaction of the cooling auxiliary means 5135a. In this case, the working fluid may be vaporized by absorbing heat from the heated substrate W while passing through the internal groove 5135b. The vaporized fluid may be liquefied by moving up inside the internal space and releasing heat to the outside through the upper surface of the second plate 5135, and then the liquefied fluid moves down again. In this way, the substrate W can be cooled by repeating vaporization and liquefaction of the working fluid.

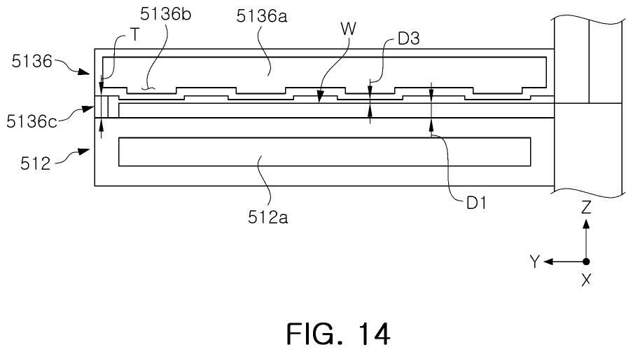

FIG. 14 illustrates a substrate cooled by a second plate and a first plate according to an exemplary embodiment of the present disclosure.

Referring to FIG. 14, a second plate 5136 according to an exemplary embodiment (hereinafter, a sixth exemplary embodiment) of the present disclosure may include a cooling auxiliary means 5136a and an internal groove 5136b. At this time, since the specific features and the substrate cooling method of the cooling auxiliary means 5136a and the internal groove 5136b are the same as those in the exemplary embodiments described above, overlapping descriptions will be omitted.

The second plate 5136 may further include a projection 5136c. The projection 5136c may be formed to project downward from the lower surface of the second plate 5136, and may be disposed at an outer end portion of the second plate 5136, similarly to those in the second and fourth exemplary embodiments. The projection 5136c makes it possible to prevent the second plate 5136 from being directly in contact with the substrate W at the cooling position.

Meanwhile, although not illustrated in the drawings, each of the second plates 5131, 5132, 5133, 5134, 5135, and 5136 according to the exemplary embodiments described above may further include a cooling fin (not illustrated). The cooling fin may be disposed on the upper surface of each of the second plates 5131, 5132, 5133, 5134, 5135, and 5136. At this time, a plurality of cooling fins may be provided and evenly arranged over the entire upper surface of each of the second plates 5131, 5132, 5133, 5134, 5135, and 5136.

In addition, each of the second plates 5131, 5132, 5133, 5134, 5135, and 5136 may further include a fan (not illustrated). The fan may be disposed on each of the second plates 5131, 5132, 5133, 5134, 5135, and 5136 to form an airflow in the third direction Z. The fan may guide air between each of the second plates 5131, 5132, 5133, 5134, 5135, and 5136 and the substrate W to move to above each of the second plates 5131, 5132, 5133, 5134, 5135, and 5136 to promote heat exchange between the substrate W and each of the second plates 5131, 5132, 5133, 5134, 5135, and 5136.

The cooling fin and fan make it possible to easily and efficiently release heat absorbed from the substrate W by each of the second plates 5131, 5132, 5133, 5134, 5135, and 5136 to the outside, thereby improving the cooling performance of the cooling unit CU.

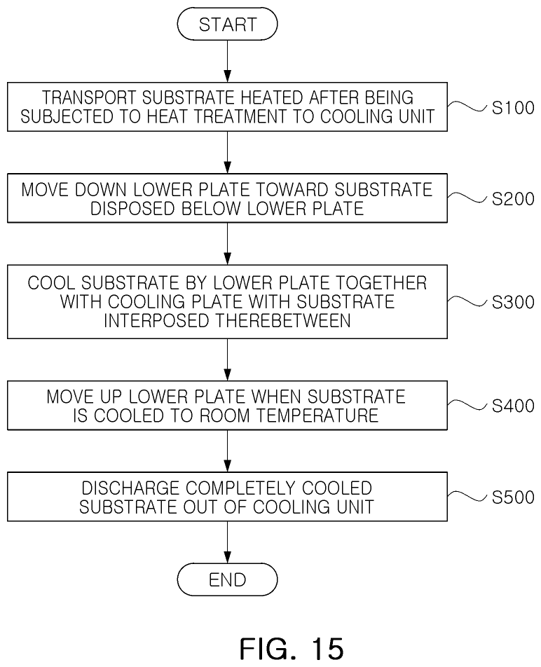

FIG. 15 is a flowchart illustrating a process in which a cooling unit cools a substrate according to an exemplary embodiment of the present disclosure.

Referring to FIGS. 5 to 14 and FIG. 15, a method by which the cooling unit CU cools the substrate W may be as follows.

First, the substrate W subjected to heat treatment in the baking chamber 510 may be transported into the cooling chamber 520 (S100). The heated substrate W may be seated on the first plate 512 of the cooling unit CU by the applicator robot 421.

Before the substrate W is seated on the first plate 512, the second plate 513 may be disposed in contact with the lower surface of the first plate 512. At this time, the second plate 513 may be cooled to room temperature or to a temperature lower than room temperature by the cooling means 512a of the first plate 512. The second plate 513 may be kept at the cooled temperature by being disposed in contact with the first plate 512 until the second plate 513 begins to move down.

Next, after the substrate W is seated and supported on the first plate 512, the second plate 513 may move down (S200). The second plate 513 may move to approach the substrate W disposed on another first plate 512 disposed immediately below the second plate 513. At this time, the second plate 513 may move to a cooling position.

Next, the heated substrate W may be cooled by the first plate 512 and the second plate 513 (S300).

In step S200, when the second plate 513 is located at the cooling position, the substrate W may be disposed between the second plate 513 and the first plate 512. More specifically, when the second plate 513 is located at the cooling position, the substrate W may be disposed in such a manner that the upper surface of the substrate W faces the lower surface of the second plate 513 in a state in which the lower surface of the substrate W is supported in contact with the first plate 512.

The heated substrate W may be cooled by the cooling means 512a of the first plate 512 supporting the substrate W. More specifically, the substrate W may be cooled by exchanging heat with a surface of the first plate 512 cooled by the cooling means 512a. At this time, the second plate 513 facing the substrate W is pre-cooled as described above and has a lower temperature than the substrate W. Thus, while the substrate W is cooled by the first plate 512, heat may be exchanged between the second plate 513 and the substrate W.

In this way, the heated substrate W exchanges heat with the first plate 512 through its lower surface and is cooled, and at the same time, the substrate W exchanges heat with the second plate 513 through its upper surface and is cooled, thereby shortening the time required for cooling as compared with that in a case in which only the first plate 512 is used.

Meanwhile, in a case in which the second plate 5133 or 5134 includes a cooling auxiliary means 5133a or 5134a as in the third or fourth exemplary embodiments described above, while the substrate W is cooled, the surface of the second plate 5133 or 5134 is continuously cooled, thereby being kept at a lower temperature than the substrate W. Accordingly, the substrate W can continuously exchange heat not only with the first plate 512 but also with the second plate 5133 or 5134. As a result, it is possible to more rapidly cool the substrate W.

Next, when the cooling of the substrate W is completed, the second plate 513 may move up again (S400). When the substrate W is cooled to a target temperature, the second plate 513 may move toward the first plate 512 located above the second plate 513 and return to its original position before cooling began. Here, the target temperature may be room temperature, that is, 15 to 25° C., and preferably 18 to 23° C. The second plate 513 that has returned to its original position may be cooled again in contact with the lower surface of the first plate 512 until the cooling of the next substrate W begins.

Next, the completely cooled substrate W may be discharged out of the cooling unit CU (S500). The substrate W cooled to the target temperature (e.g., room temperature) may be transported to the outside of the cooling chamber 520 by the transfer robot 640. By repeating this process, a plurality of substrates W may be sequentially and continuously cooled, and then transported to a location for the next process.

The cooling unit CU and the substrate treatment apparatus 1 according to the exemplary embodiments of the present disclosure as described above are capable of simultaneously cooling the upper and lower surfaces of the substrate W using the second plate 513 pre-cooled by the first plate 512 and the first plate 512, thereby increasing the cooling rate as compared with that in a case in which the substrate W is cooled using only the first plate 512, and as a result, improving the substrate treatment amount and substrate treatment performance of the substrate treatment apparatus 1.

In addition, the configurations of the above-described exemplary embodiments may be combined with each other as long as the technical contents do not contradict each other without departing from the technical idea of the present disclosure, which also falls within the scope of the present disclosure.

Although it has been described in the above exemplary embodiments that the substrate treatment apparatus according to the present disclosure is applied to a photo process, but the present disclosure is not limited thereto. As long as the substrate treatment apparatus according to the present disclosure can be used as a substrate cooling apparatus, it is obvious to those skilled in the art that the substrate treatment apparatus according to the present disclosure can be applied to various processes such as etching processes, testing processes, and packaging processes, which also falls within the scope of the present disclosure.

What is claimed is:

1. A substrate treatment apparatus comprising:
a cooling chamber accommodating a substrate; and
a cooling unit disposed inside the cooling chamber, the cooling unit including a support, two first plates connected to the support to support the substrate and spaced apart from each other in a height direction of the support, and a second plate disposed to move up and down between the two first plates.

2. The substrate treatment apparatus of claim 1, wherein the first plate includes a coolant inlet through which a coolant is introduced, a coolant outlet through which the coolant is discharged, and a cooling passage disposed inside the first plate.

3. The substrate treatment apparatus of claim 1, wherein the second plate is in contact with the upper one of the two first plates before cooling the substrate, and the second plate moves down to a cooling position spaced apart from the substrate supported on the lower one of the two first plates while cooling the substrate.

4. The substrate treatment apparatus of claim 3, wherein a lower surface of the second plate and an upper surface of the substrate are spaced apart from each other by a distance shorter than a thickness of the substrate.

5. The substrate treatment apparatus of claim 1, wherein the second plate has a cross-sectional shape corresponding to the first plates, and has an area entirely covering the substrate.

6. The substrate treatment apparatus of claim 5, wherein the second plate has a projection, and
the projection is formed to project downward from a lower surface of the second plate.

7. The substrate treatment apparatus of claim 6, wherein the projection has a projection distance longer than a thickness of the substrate.

8. The substrate treatment apparatus of claim 6, wherein the projection is disposed on an edge portion of the second plate, and extends along a circumferential direction of the second plate.

9. The substrate treatment apparatus of claim 1, wherein the two first plates and the second plate are arranged in parallel with each other.

10. The substrate treatment apparatus of claim 1, wherein the second plate has an internal space, and
the internal space accommodates a working fluid.

11. A substrate treatment method comprising:
seating a substrate on a first plate cooling the substrate;
moving a second plate down toward the substrate;
cooling the substrate using the second plate, together with the first plate; and
moving the second plate up after completely cooling the substrate.

12. The substrate treatment method of claim 11, wherein a plurality of first plates are provided and spaced apart from each other along one direction, and
the second plate moves up and down between two adjacent ones of the plurality of first plates.

13. The substrate treatment method of claim 12, wherein in the seating of the substrate on the first plate cooling the substrate, the second plate is cooled by contacting a lower surface of the upper one of the two first plates.

14. The substrate treatment method of claim 12, wherein in the moving down of the second plate toward the substrate, the second plate moves down toward the lower one of the two first plates.

15. The substrate treatment method of claim 14, wherein in the cooling of the substrate by the second plate together with the first plate, the substrate is cooled in a state in which a lower surface of the substrate is in contact with the first plate, and an upper surface of the substrate is spaced apart from the second plate.

16. The substrate treatment method of claim 14, wherein the second plate has a projection, and
the projection projects downward from a lower surface of the second plate, and has a projection distance longer than a thickness of the substrate.

17. The substrate treatment method of claim 16, wherein in the cooling of the substrate by the second plate together with the first plate, the substrate is cooled in a state in which the projection is in contact with the lower first plate, and the substrate is spaced apart from the second plate.

18. The substrate treatment method of claim 13, wherein in the moving up of the second plate after completely cooling the substrate, when the substrate is cooled to a target temperature, the second plate moves to come into contact with the lower surface of the upper first plate again.

19. A substrate treatment apparatus comprising:
a baking chamber heating a substrate for heat treatment;
a cooling chamber disposed on one side of the baking chamber, and accommodating the substrate heat-treated in the baking chamber; and
a cooling unit disposed inside the cooling chamber, the cooling unit including a support, two first plates connected to the support to support the substrate and spaced apart from each other in a height direction of the support, and a second plate, movable up and down between the two first plates, and disposed in parallel with the two first plates,
wherein the second plate has a projection projecting downwardly from a lower surface thereof by a projection distance longer than a thickness of the substrate and extending in a circumferential direction of the second plate.

20. The substrate treatment apparatus of claim 19, wherein the first plate includes a coolant inlet through which a coolant is introduced, a coolant outlet through which the coolant is discharged, and a cooling passage disposed inside the first plate, and
the second plate has an internal space accommodating a working fluid.
